(19) United States
(12) Patent Application Publication
(10) Pub. No.: US 2021/0111288 A1
(43) Pub. Date: Apr. 15, 2021

(54) BACK PANEL OF SOLAR CELL AND METHOD FOR MANUFACTURING THE SAME

(71) Applicant: NAN YA PLASTICS CORPORATION, Taipei (TW)

(72) Inventors: TE-CHAO LIAO, TAIPEI (TW); CHING-YAO YUAN, TAIPEI (TW); Ming-lang Liu, TAIPEI (TW)

(21) Appl. No.: 16/909,458

(22) Filed: Jun. 23, 2020

(30) Foreign Application Priority Data
Oct. 15, 2019 (TW) 108136973

(51) Int. Cl. H01L 31/0232; H01L 31/0256; H01L 31/0216

(52) U.S. Cl. CPC H01L 31/02327; H01L 2031/0344; H01L 31/02168; H01L 31/0256

(57) ABSTRACT

A back panel of a solar cell and a method for manufacturing the same are provided. The back panel includes a polyolefin laminate structure and a protective layer disposed on the polyolefin laminate structure. The polyolefin laminate structure includes a reflective layer and a transparent layer disposed on the reflective layer. The transparent layer includes a continuous phase and a dispersed phase dispersed in the continuous phase. The continuous phase is formed from polyolefin. The dispersed phase is formed from a rubber elastomer. Based on the total weight of the transparent layer, an amount of the dispersed phase ranges from 10 wt % to 25 wt %.

### CROSS-REFERENCE TO RELATED PATENT APPLICATION

This application claims the benefit of priority to Taiwan Patent Application No. 108136973, filed on Oct. 15, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a back panel and a method for manufacturing the same, and more particularly to a back panel of a solar cell and a method for manufacturing the same.

### BACKGROUND OF THE DISCLOSURE

Generally, a solar cell module includes a glass cover, an ethylene-vinyl acetate copolymer (EVA), a solar cell, and a back panel. The back panel is the component of the solar cell module which has a largest contact area with the exterior environment. The back panel can not only support the whole solar cell module, but also shield the solar cell from the exterior environment so as to protect the solar cell.

In order to receive light energy, the solar cell module is usually constructed outdoors. Accordingly, the solar cell module requires good weather resistance and heat resistance so as to withstand sun and rain. In addition, the solar cell module also requires good barrier property and impact resistance to prevent dust particles, liquid, or water vapor in outer environment from permeating thereinto. If dust particles, liquid, or water vapor in outer environment permeates into the solar cell module, the solar cell may be damaged and the photoelectric conversion efficiency may be negatively influenced. Therefore, for the solar cell module, weather resistance, heat resistance, barrier property, and impact resistance of the back panel are important factors that contribute to prolonging a service life of the solar cell module.

Conventional back panel of the solar cell includes a transparent polyolefin film used as a penetrating layer, a polyester film (such as polyethylene terephthalate film) used as a reflective layer, and a protective layer. However, due to the material difference, the polyester film is required to go through a composite process so that the penetrating layer and the protective layer can be disposed on two opposite surfaces of the polyester film so as to manufacture the back panel. In other words, at least two composite processes are required in the manufacturing process of the conventional back panel. However, a cost of the composite process is high, and imperfections may be generated during the composite process. In addition, an adhesive is involved in the composite process. The adhesive may age as time goes by and lose its adhesive strength. Moreover, if water vapor permeates into the structure of the back panel, the adhesive strength of the adhesive may be weakened and result in a peeling phenomenon in a laminate structure of the back panel.

### SUMMARY OF THE DISCLOSURE

In response to the above-referenced technical inadequacies, the present disclosure provides a back panel of a solar cell and a method for manufacturing a back panel of a solar cell.

In one aspect, the present disclosure provides a back panel of a solar cell. The back panel includes a polyolefin laminate structure and a protective layer. The polyolefin laminate structure includes a reflective layer and a transparent layer disposed on the reflective layer. The transparent layer includes a continuous phase and a dispersed phase dispersed in the continuous phase. The continuous phase is formed from polyolefin and the dispersed phase is formed from rubber elastomer. An amount of the dispersed phase in the transparent layer ranges from 10 wt % to 25 wt %. The protective layer is disposed on the polyolefin laminate structure.

In certain embodiments, the present disclosure provides a back panel of a solar cell. Based on a total weight of the transparent layer, an amount of the dispersed phase ranges from 12 wt % to 24 wt %, and the continuous phase includes 48 wt % to 56 wt % of polypropylene and 20 wt % to 40 wt % of polyethylene.

In certain embodiments, the present disclosure provides a back panel of a solar cell. The rubber elastomer is ethylene-propylene rubber. An amount of ethylene in the ethylene-propylene rubber ranges from 25 wt % to 55 wt %.

In certain embodiments, the present disclosure provides a back panel of a solar cell. A material of the reflective layer is polyolefin. The reflective layer and the transparent layer are formed integrally by co-extrusion.

In certain embodiments, the present disclosure provides a back panel of a solar cell. Based on a total weight of the reflective layer, a material of the reflective layer includes 30 wt % to 60 wt % of polypropylene and 40 wt % to 70 wt % of polyethylene.

In certain embodiments, the present disclosure provides a back panel of a solar cell. Based on a total weight of the reflective layer, the reflective layer includes 10 wt % to 35 wt % of reflective fillers.

In certain embodiments, the present disclosure provides a back panel of a solar cell. A thickness of the protective layer is 15 μm to 25 μm.

In certain embodiments, the present disclosure provides a back panel of a solar cell. A material of the protective layer includes a fluorine-containing polymer. The fluorine-containing polymer includes one or more of polyvinylidene fluoride, polytetrafluoroethylene, ethylene-tetrafluoroethylene copolymer, polychlorotrifluoroethylene, and ethylene-polychlorotrifluoroethylene copolymer.

In certain embodiments, the present disclosure provides a back panel of a solar cell. The protective layer contacts the transparent layer.

In another aspect, the present disclosure provides a method for manufacturing a back panel of a solar cell. The method includes steps of providing a polyolefin laminate structure, and forming a protective layer onto the polyolefin laminate structure. The polyolefin laminate structure includes a reflective layer and a transparent layer stacked together. The transparent layer includes a continuous phase and a dispersed phase. The continuous phase is formed from polyolefin and the dispersed phase is formed from rubber elastomer. An amount of the dispersed phase in the transparent layer ranges from 10 wt % to 25 wt %.

In certain embodiments, the present disclosure provides a method for manufacturing a back panel of a solar cell. The reflective layer and the transparent layer are formed integrally by co-extrusion.

In certain embodiments, the present disclosure provides a method for manufacturing a back panel of a solar cell. The protective layer is formed on the polyolefin laminate structure by coating.

Therefore, by virtue of “the transparent layer includes a continuous phase and a dispersed phase dispersed in the continuous phase”, “the continuous phase is formed from polyolefin and the dispersed phase is formed from rubber elastomer”, and “an amount of the dispersed phase in the transparent layer ranges from 10 wt % to 25 wt %”, the back panel of the present disclosure has good weather resistance, heat resistance, barrier property, and impact resistance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is an exploded view of a solar cell module.

FIG. 2 is a side view of a back panel of a solar cell of the present disclosure.

FIG. 3 is a flowchart of a method for manufacturing the back panel of the solar cell of the present disclosure.

FIG. 4 is a side view of a microscopic structure of a transparent layer of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

Referring to FIG. 1, FIG. 1 is an exploded view of a solar cell module. The solar cell module includes a glass cover G, an ethylene-vinyl acetate copolymer (EVA) layer F, a solar cell S, another ethylene-vinyl acetate copolymer layer F, and a back panel B.

Many types of solar cells exist in the market. The back panel B of the present disclosure can be applied in various solar cells S, such as crystalline silicon solar cell or thin film solar cell, but is not limited thereto. The two ethylene-vinyl acetate copolymer layers F on the two opposite surfaces of the solar cell S are used as a packaging material. The solar cell S is completely encapsulated and protected by the two ethylene-vinyl acetate copolymer layers F. In addition, the glass cover G is disposed on one side of the solar cell S facing to light. The glass cover G can bar particles from the exterior environment from contacting the solar cell S, thereby preventing a negative influence on the light conversion efficiency of the solar cell S. The back panel B is disposed on the other side of the solar cell S. The specific structure of the back panel B is illustrated below.

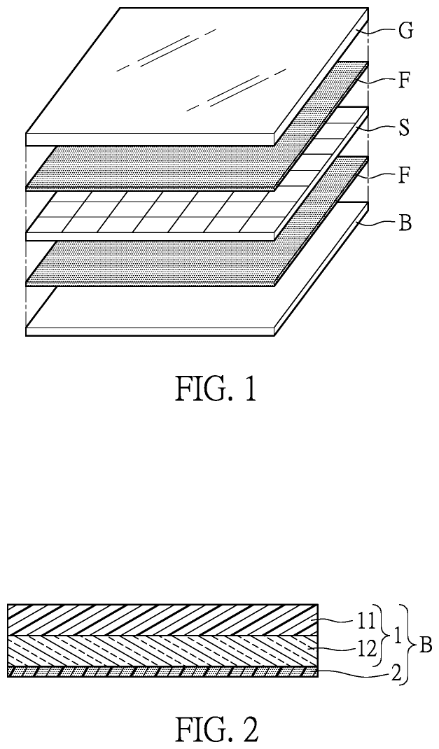

Referring to FIG. 2 and FIG. 3, FIG. 2 is a side view of the back panel of the solar cell of the present disclosure, and FIG. 3 is a flowchart of a method for manufacturing the back panel of the solar cell. In the present disclosure, the back panel B includes a polyolefin laminate structure 1 and a protective layer 2. The protective layer 2 is disposed on the polyolefin laminate structure 1 so as to protect the polyolefin laminate structure 1.

In the method for manufacturing the back panel of the solar cell, the polyolefin laminate structure 1 is provided (step S100). The polyolefin laminate structure 1 has good light reflective property. Scattered light can be reflected by the polyolefin laminate structure 1 toward the solar cell S, thereby enhancing the light utilization and light conversion efficiency of the solar cell S of the solar cell module. Further, the polyolefin laminate structure 1 has good weather resistance, heat resistance, barrier property, and impact resistance. The polyolefin laminate structure 1 can protect the solar cell S and prevent outer environmental factors, such as temperature or humidity, from negatively influencing the efficacy of the solar cell S. The protective layer 2 has good anti-erosion property. The protective layer 2 can protect the solar cell S from erosion.

It should be noted that the polyolefin laminate structure 1 is manufactured by co-extrusion. Therefore, a coating of an adhesive or a disposition of an adhesive layer is not required during manufacturing the polyolefin laminate structure 1. The protective layer 2 is formed on the polyolefin laminate structure 1 by coating. Similarly, the adhesive or the adhesive layer is not required during disposing the protective layer 2. Accordingly, the method for manufacturing the back panel B of the present disclosure can exclude the usage of the adhesive and omit the composite process. Therefore, the present disclosure has advantages of low manufacture cost and can solve the problem of the weakening of adhesive strength caused by water vapor permeation.

Specifically, the polyolefin laminate structure 1 includes a reflective layer 11 and a transparent layer 12 disposed on the reflective layer 11. The reflective layer 11 and the transparent layer 12 can be manufactured in the same process by co-extrusion. In other words, the reflective layer 11 and the transparent layer 12 can be formed integrally so that the reflective layer 11 and the transparent layer 12 are tightly connected. Accordingly, the reflective layer 11 and the transparent layer 12 are not easily separated from each other due to the permeation of water vapor into the polyolefin laminate structure 1. Furthermore, compared to polyester, polyolefin has better water-proof property.

In the present disclosure, a material of the reflective layer 11 and a material of the transparent layer 12 are both polyolefin. Therefore, the reflective layer 11 and the transparent layer 12 can be combined without adding additional bridging agent after heat compression during the co-extrusion process. However, the method for manufacturing the polyolefin laminate structure 1 is used only for exemplary purposes, and should not be taken as a limitation of the scope of the present disclosure.

The reflective layer 11 of the polyolefin laminate structure 1 can reflect scattered light not received by the solar cell S toward the solar cell S, so that light utilization and light conversion efficiency of the solar cell S can be enhanced. In the present disclosure, based on the total weight of the reflective layer 11, the material of the reflective layer 11 includes 30 wt % to 60 wt % of polypropylene and 40 wt % to 70 wt % of polyethylene.

Specifically, polypropylene can be propylene homopolymer (PP-H), propylene block copolymer (PP-B), or polypropylene random copolymer (PP-R). In a preferable embodiment, polypropylene in the reflective layer 11 is propylene homopolymer.

Specifically, polyethylene can be ethylene homopolymer, ethylene copolymer, or a mixture thereof. Ethylene homopolymer is polymerized from only ethylene as monomers. Ethylene copolymer is polymerized from ethylene and other monomers. In addition, polyethylene can be classified into high density polyethylene (HDPE), low density polyethylene (LDPE), linear low density polyethylene (LLDPE), or metallocene polyethylene (mPE), but is not limited thereto. In a preferable embodiment, polyethylene in the reflective layer 11 is linear polyethylene.

In addition, the material of the reflective layer 11 can further include 10 wt % to 35 wt % of reflective fillers so as to enhance the reflective property of the reflective layer 11. The reflective fillers can be titanium dioxide, montmorillonite (MMT), silicon dioxide, aluminum paste, mica powder, barium sulfate, or calcium carbonate, but is not limited thereto. In a preferable embodiment, the reflective fillers are titanium dioxide. Titanium dioxide can enhance not only light conversion efficiency of the solar cell module, but also weather resistance of the reflective layer 11 so that the service life of the solar cell module is prolonged.

The transparent layer 12 of the polyolefin laminate structure 1 has good weather resistance, heat resistance, barrier property, and impact resistance. Therefore, the transparent layer 12 can protect the solar cell S and prolong the service life of the solar cell module. In the present embodiment, based on the total weight of the transparent layer 12, the transparent layer 12 includes 60 wt % to 80 wt % of polypropylene and 20 wt % to 40 wt % of polyethylene. Further, the polypropylene contains 20 wt % to 30 wt % of rubber elastomer. In other words, based on the total weight of the transparent layer 12, the transparent layer 12 includes 12 wt % to 24 wt % of rubber elastomer, but is not limited thereto. Preferably, based on the total weight of the transparent layer 12, the transparent layer 12 includes 10 wt % to 25 wt % of rubber elastomer. More preferably, the transparent layer 12 includes 20 wt % to 25 wt % of rubber elastomer. The addition of the rubber elastomer can enhance the rigidity of the transparent layer 12. Therefore, the polyolefin laminate structure 1 can possess physical properties close to physical properties of conventional polyester film.

Specifically, the rubber elastomer can be based on ethylene monomer or propylene monomer. When the rubber elastomer is based on ethylene, ethylene monomer can be polymerized with propylene, butylene, and/or octylene. When the rubber elastomer is based on propylene, propylene monomer can be polymerized with ethylene, butylene, and/or octylene. Accordingly, a polyolefin elastomer (POE) is synthesized. On the other hand, the rubber elastomer can be formed by mixing polyethylene, polypropylene, and/or other olefin-type material. For example, olefin-type material can be, but is not limited to ethylene-propylene copolymer rubber (EPM) or ethylene-propylene terpolymer rubber (EPDM). Accordingly, a thermoplastic olefin elastomer (TPO) is formed.

In a preferable embodiment, the polypropylene in the transparent layer 12 is polypropylene block copolymer (PP-B), the polyethylene in the transparent layer 12 is linear polyethylene, and the rubber elastomer in the transparent layer 12 is ethylene-propylene rubber. The contents of ethylene and propylene in the ethylene-propylene rubber can be adjusted during polymerization. Preferably, the ethylene-propylene rubber contains 25 wt % to 55 wt % of ethylene. More preferably, the ethylene-propylene rubber contains 30 wt % to 50 wt % of ethylene. When the amount of ethylene of the ethylene-propylene rubber is lower than 25 wt % or higher than 55 wt %, the transparent layer 12 cannot have good impact resistance.

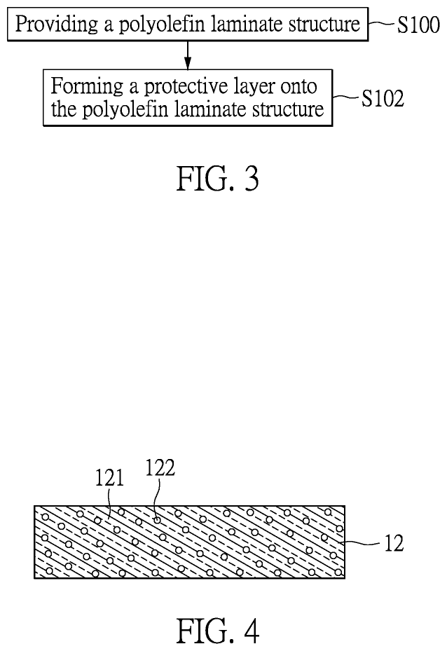

Referring to FIG. 4, at a microscopic perspective view, the transparent layer 12 includes a continuous phase 121 and a dispersed phase 122. The dispersed phase 122 is dispersed in the continuous phase 121.

In the present disclosure, a material of the continuous phase 121 is polyolefin; that is, the continuous phase 121 is formed from the foresaid polyethylene and the foresaid polypropylene. By adjusting the weight ratio of polyethylene and polypropylene, hardness and the mechanical strength of the transparent layer 12 can be adjusted to be comparable with polyester film Specifically, based on the total weight of the transparent layer 12, the material of the continuous phase 121 includes 48 wt % to 56 wt % of polypropylene and 20 wt % to 40 wt % polyethylene. On the other hand, a material of the dispersed phase 122 is rubber elastomer. That is, the dispersed phase 122 is formed from the foresaid ethylene-propylene rubber. The addition of rubber elastomer can enhance the impact resistance of the transparent layer 12.

The transparent layer 12 can have good film-forming property and impact resistance by adjusting the amount of the dispersed phase 122 in the transparent layer 12. If the amount of the dispersed phase 122 in the transparent layer 12 is too high, the film-forming property and the adhesive property of the transparent layer 12 will be weakened and properties of the back panel B will be negatively influenced. If the amount of the dispersed phase 122 in the transparent layer 12 is too low, the transparent layer 12 cannot possess adequate heat resistance and impact resistance.

Referring to FIG. 2 and FIG. 3, in the method for manufacturing the back panel of the solar cell, a protective layer 2 is formed onto the polyolefin laminate structure 1 (step S102). The protective layer 2 is disposed on the polyolefin laminate structure 1, and the protective layer 2 contacts the reflective layer 11 or the transparent layer 12. In the present embodiment, the protective layer 2 is disposed on the polyolefin laminate structure 1 and contacts the transparent layer 12. Accordingly, when the back panel B is applied in the solar cell module, scattered light not received by the solar cell S can be reflected by the reflective layer 11 in an optical path that is shorter in length. Therefore, the energy loss of light can be reduced and light conversion efficiency of the solar cell module can be increased. However, the present disclosure is not limited thereto.

A material of the protective layer 2 includes a fluorine-containing polymer so as to resist erosion. The fluorine-containing polymer includes one or more of polyvinylidene difluoride (PVDF), polytetrafluoroethylene (PTFE), polyethylene tetrafluoroethylene (ETFE), polychlorotrifluoroethene (PCTFE), and polyethylene chlorotrifluoroethene (ECTFE). In a preferable embodiment, the fluorine-containing polymer is polyethylene tetrafluoroethylene (ETFE), and a thickness of the protective layer 2 ranges from 15 μm to 25 μm.

In conclusion, the back panel of the solar cell and the method for manufacturing the same of the present disclosure have technical features of “the transparent layer 12 includes a continuous phase 121 and a dispersed phase 122 dispersed in the continuous phase 121”, “the continuous phase 121 is formed from polyolefin and the dispersed phase 122 is formed from rubber elastomer”, and “an amount of the dispersed phase 122 in the transparent layer 12 ranges from 10 wt % to 25 wt %” so as to enhance the weather resistance, heat resistance, barrier property, and impact resistance of the back panel B.

Further, the back panel of the solar cell and the method for manufacturing the same of the present disclosure have technical features of “the reflective layer 11 and the transparent layer 12 are formed integrally by co-extrusion” and “the protective layer 2 is formed on the polyolefin laminate structure 1 by coating” so that the adhesive can be excluded, and the material cost and the defect rate of products can be decreased. In addition, the problem of the weakening of adhesive strength caused by the ageing of the adhesive after being used for a long time or caused by the permeation of water vapor can be prevented.

Further, the back panel of the solar cell and the method for manufacturing the same of the present disclosure have the technical feature of “a material of the continuous phase 121 includes 48 wt % to 56 wt % of polypropylene and 20 wt % to 40 wt % of polyethylene” or “ethylene-propylene rubber contains 25 wt % to 55 wt % of polyethylene” so that hardness of the transparent layer 12 can compete with the hardness of conventional polyester film, and the transparent layer 12 can have adequate barrier property and impact resistance.

Further, the back panel B of the solar cell and the method for manufacturing the same of the present disclosure have the technical feature of “the reflective layer 11 includes 10 wt % to 35 wt % of reflective fillers” so that the reflective layer 11 can reflect more scattered light toward the solar cell S, thereby enhancing light conversion efficiency of the solar cell module.

Further, the back panel of the solar cell and the method for manufacturing the same of the present disclosure have the technical feature of “the protective layer 2 contacts the transparent layer 12” so that the optical path for the scattered light not received by the solar cell S to be reflected by the reflective layer 11 can be shortened. Therefore, the energy loss of light can be decreased, and light conversion efficiency of the solar cell module can be enhanced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A back panel of a solar cell, comprising:
a polyolefin laminate structure including a reflective layer and a transparent layer disposed on the reflective layer; wherein the transparent layer includes a continuous phase and a dispersed phase dispersed in the continuous phase, the continuous phase is formed from polyolefin, the dispersed phase is formed from rubber elastomer, and an amount of the dispersed phase in the transparent layer ranges from 10 wt % to 25 wt %; and
a protective layer disposed on the polyolefin laminate structure.

2. The back panel of the solar cell according to claim 1, wherein based on a total weight of the transparent layer, an amount of the dispersed phase ranges from 12 wt % to 24 wt %, and the continuous phase includes 48 wt % to 56 wt % of polypropylene and 20 wt % to 40 wt % of polyethylene.

3. The back panel of the solar cell according to claim 1, wherein the rubber elastomer is ethylene-propylene rubber, and an amount of ethylene in the ethylene-propylene rubber ranges from 25 wt % to 55 wt %.

4. The back panel of the solar cell according to claim 1, wherein a material of the reflective layer is polyolefin, and the reflective layer and the transparent layer are formed integrally by co-extrusion.

5. The back panel of the solar cell according to claim 1, wherein based on a total weight of the reflective layer, a material of the reflective layer includes 30 wt % to 60 wt % of polypropylene and 40 wt % to 70 wt % of polyethylene.

6. The back panel of the solar cell according to claim 1, wherein based on a total weight of the reflective layer, the reflective layer includes 10 wt % to 35 wt % of reflective fillers.

7. The back panel of the solar cell according to claim 1, wherein a thickness of the protective layer is 15 μm to 25 μm.

8. The back panel of the solar cell according to claim 1, wherein a material of the protective layer includes a fluorine-containing polymer, and the fluorine-containing polymer includes one or more of polyvinylidene fluoride, polytetrafluoroethylene, ethylene-tetrafluoroethylene copolymer, polychlorotrifluoroethylene, and ethylene-polychlorotrifluoroethylene copolymer.

9. The back panel of the solar cell according to claim 1, wherein the protective layer contacts the transparent layer.

10. A method for manufacturing a back panel of a solar cell, comprising:
providing a polyolefin laminate structure, wherein the polyolefin laminate structure includes a reflective layer and a transparent layer stacked together, the transparent layer includes a continuous phase and a dispersed phase, the continuous phase is formed from polyolefin, the dispersed phase is formed from rubber elastomer, and an amount of the dispersed phase in the transparent layer ranges from 10 wt % to 25 wt %; and
forming a protective layer onto the polyolefin laminate structure.

11. The method according to claim 10, wherein the reflective layer and the transparent layer are formed integrally by co-extrusion.

12. The method according to claim 10, wherein the protective layer is formed on the polyolefin laminate structure by coating.
